(19) United States
(12) Patent Application Publication
(10) Pub. No.: US 2026/0133463 A1
(43) Pub. Date: May 14, 2026

(54) LCM STRUCTURE AND FABRICATING METHOD OF THE SAME

(71) Applicant: UNITED MICROELECTRONICS CORP., Hsin-chu City (TW)

(72) Inventors: Chih-Wei Kuo, Tainan City (TW); Chung-Yi Chiu, Tainan City (TW)

(73) Assignee: UNITED MICROELECTRONICS CORP., Hsin-Chu city (TW)

(21) Appl. No.: 18/973,116

(22) Filed: Dec. 9, 2024

(30) Foreign Application Priority Data
Nov. 11, 2024 (TW) 113143166

(51) Int. Cl. G02F 1/29; H10F 77/40

(52) U.S. Cl. CPC G02F 1/292; H10F 77/413

(57) ABSTRACT

An LCM structure includes a composite dielectric layer. The composite dielectric layer includes a nitrogen-doped silicon carbide layer, a silicon oxide layer and a silicon nitride layer stacked from bottom to top. A first metal rail includes a pedestal and a metal strip. The first metal rail embedded in the silicon oxide layer and the nitrogen-doped silicon carbide layer is defined as the pedestal, and the first metal rail embedded in the silicon nitride layer and protruding on the silicon nitride layer is defined as the metal strip. The width of the pedestal in the silicon oxide layer continuously and gradually increases along a direction toward the nitrogen-doped silicon carbide layer. A second metal rail is disposed at one side of the first metal rail. A gap is disposed between the first metal rail and the second metal rail. Nemours liquid crystals fill the gap.

### BACKGROUND OF THE INVENTION

### 1. Field of the Invention

The invention relates to a light control metasurface (LCM) structure and a fabricating method of the same, and more particularly to a fabricating method of preventing metal rails of the LCM structure from collapsing during an etching process.

### 2. Description of the Prior Art

LiDAR (Light Detection and Ranging) is a sensing technology that emits a low-power, eye-safe laser to measure the time it takes for the laser to complete a round trip between a sensor and a target. LiDAR can be used in home security systems, barcode scanners, facial recognition systems and self-driving cars. Unlike radar and sonar, LiDAR provides three-dimensional data with high-resolution, making it an important tool in many fields such as automotive industry, geology, and agriculture.

Light control metasurface (LCM) is arranged in a semiconductive chip that can deflect laser pulses according to light refraction principle. The sensing quality of the LiDAR can be improved by incorporating LCM, and the fabricating cost of LiDAR can be reduced by using semiconductor manufacturing process.

### SUMMARY OF THE INVENTION

In view of this, the present invention provides a fabricating method of an LCM structure to achieve a better yield of the LCM structure.

According to a preferred embodiment of the present invention, an LCM structure includes a composite dielectric layer including a nitrogen-doped silicon carbide (SiCN) layer, a silicon oxide layer and a silicon nitride layer stacked from bottom to top. A first metal rail includes a pedestal and a metal strip. The first metal rail embedded in the silicon oxide layer and the nitrogen-doped silicon carbide layer is defined as the pedestal. The first metal rail embedded in the silicon nitride layer and protruding on the silicon nitride layer is defined as the metal strip. A width of the pedestal in the silicon oxide layer continuously and gradually increases along a direction toward the nitrogen-doped silicon carbide layer. A second metal rail is disposed at one side of the first metal rail, wherein a structure of the first metal rail is the same as a structure of the second metal rail. A gap is disposed between the first metal rail and the second metal rail. Numerous liquid crystals fill the gap.

According to another preferred embodiment of the present invention, a fabricating method of an LCM structure including providing a first dielectric layer, a composite dielectric layer and a second dielectric layer stacked from bottom to top, wherein the composite dielectric layer includes a nitrogen-doped silicon carbide layer, a silicon oxide layer and a silicon nitride layer stacked from bottom to top. Next, a first trench is formed to be embedded in the second dielectric layer and the silicon nitride layer. After forming the first trench, an isotropic etching process is performed to etch the silicon oxide layer by using a first etchant so as to extend a bottom of the first trench into the silicon oxide layer. After the isotropic etching process, an anisotropic etching process is performed to etch the nitrogen-doped silicon carbide layer by using a second etchant so as to extend the bottom of the first trench into the nitrogen-doped silicon carbide layer. After the anisotropic etching process, a barrier layer is formed to cover the first trench. After forming the barrier layer, a metal layer is formed to fill in the first trench. Later, an entirety of the second dielectric layer and the barrier layer in the second dielectric layer are removed to form a gap. Finally, liquid crystals are provided to fill the gap.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 depicts a fabricating method of an LCM structure according to a preferred embodiment of the present invention, wherein:

FIG. 2 depicts a fabricating step in continuous of FIG. 1;

FIG. 3 depicts a fabricating step in continuous of FIG. 2;

FIG. 4 depicts a fabricating step in continuous of FIG. 3;

FIG. 5 depicts a fabricating step in continuous of FIG. 4;

FIG. 6 depicts a fabricating step in continuous of FIG. 5; and

FIG. 7 depicts a fabricating step in continuous of FIG. 6.

### DETAILED DESCRIPTION

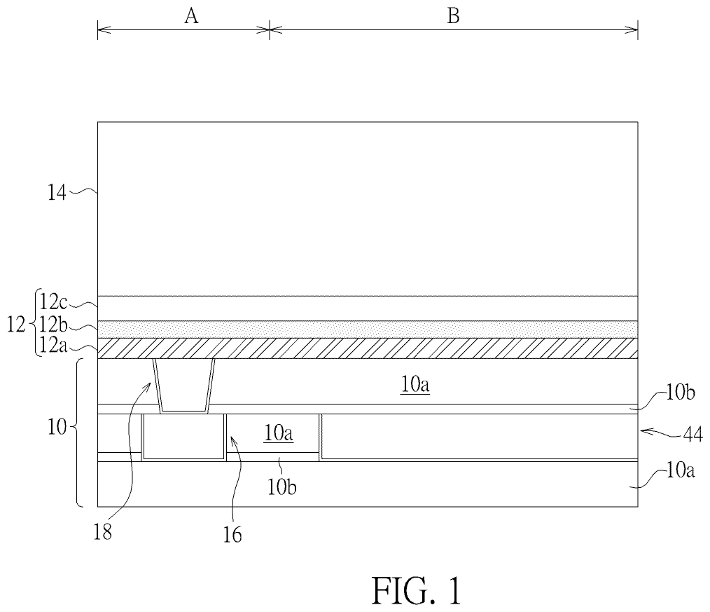

As shown in FIG. 1, a first dielectric layer 10, a composite dielectric layer 12 and a second dielectric layer 14 are provided. The first dielectric layer 10, the composite dielectric layer 12 and the second dielectric layer 14 are stacked from bottom to top in a listed sequence. The composite dielectric layer 12 includes a nitrogen-doped silicon carbide layer 12a, a silicon oxide layer 12b and a silicon nitride layer 12c stacked from bottom to top. The first dielectric layer 10, the composite dielectric layer 12 and the second dielectric layer 14 are all divided into a logic element region A and an optical element region B. A first conductive line 16 and a first plug 18 are disposed in the logic element region A of the first dielectric layer 10. The first plug 18 is disposed on the first conductive line 16. A reflective layer 44 is disposed in the optical element region B of the first dielectric layer 10. The top surface of the first conductive line 16 is aligned with the top surface of the reflective layer 44.

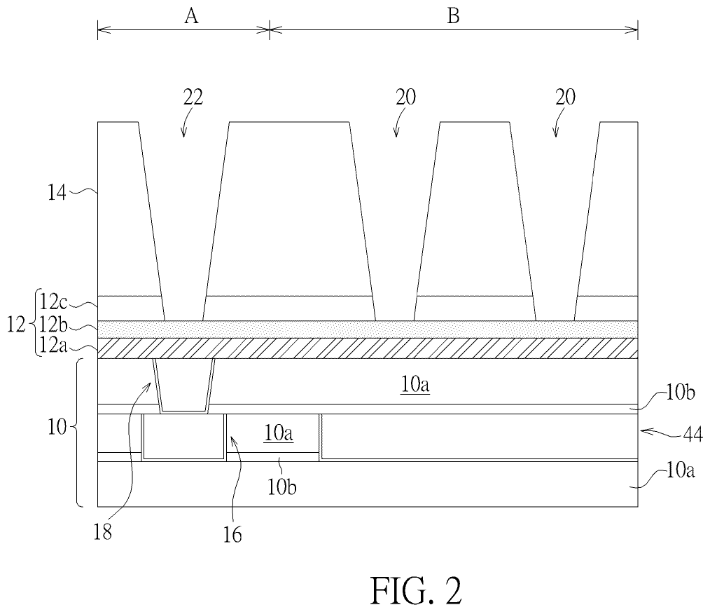

As shown in FIG. 2, a first trench 20 and a second trench 22 are formed simultaneously. The first trench 20 is embedded in the second dielectric layer 14 and the silicon nitride layer 12c of the optical element region B. The second trench 22 is embedded in the second dielectric layer 14 and the silicon nitride layer 12c of the logic element region A. According to a preferred embodiment of the present invention, the steps of forming the first trench 20 and the second trench 22 include etching the second dielectric layer 14 by using an anisotropic etching process with CF₄ serving as an etchant. Then, the silicon nitride layer 12c is etched by using C₄F₆ as an etchant. At this time, the bottom of the first trench 20 and the bottom of the second trench 22 are both in the silicon nitride layer 12c. The number of the first trench 20 and the second trench 22 is not limited. The number of the first trench 20 is preferably two or more than two.

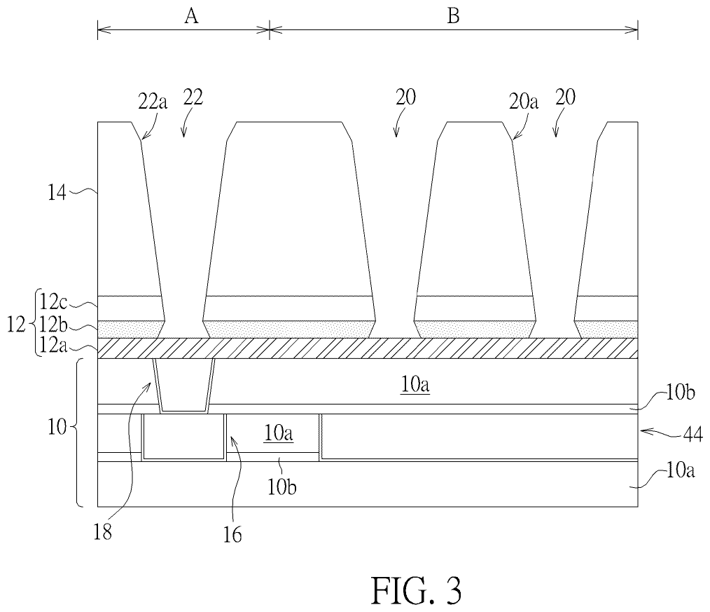

As shown in FIG. 3, an isotropic etching process is performed to etch the silicon oxide layer 12b at the bottom of the first trench 20 and at the bottom of the second trench 22 by using a first etchant so as to respectively extend the bottom of the first trench 20 and the bottom of the second trench 22 into the silicon oxide layer 12b. The first etchant includes CF₄. Because the etching process is an isotropic etching, during the process of etching the silicon oxide layer 12b, the width of the bottom of the first trench 20 and the width of the bottom of the second trench 22 will continuously and gradually expand outward. At this time, the bottom of the first trench 20 and the bottom of the second trench 22 are both located in the silicon oxide layer 12b. Moreover, in this embodiment, the second dielectric layer 14 is preferably silicon oxide, therefore the second dielectric layer 14 is also etched by the first etchant. In this way, during the isotropic etching process, the opening of the first trench 20 and the opening of the second trench 22 are both widened, thus corners 20a/22a are respectively formed at the sidewall close to the opening of the first trench 20 and at the sidewall close to the opening of the second trench 22.

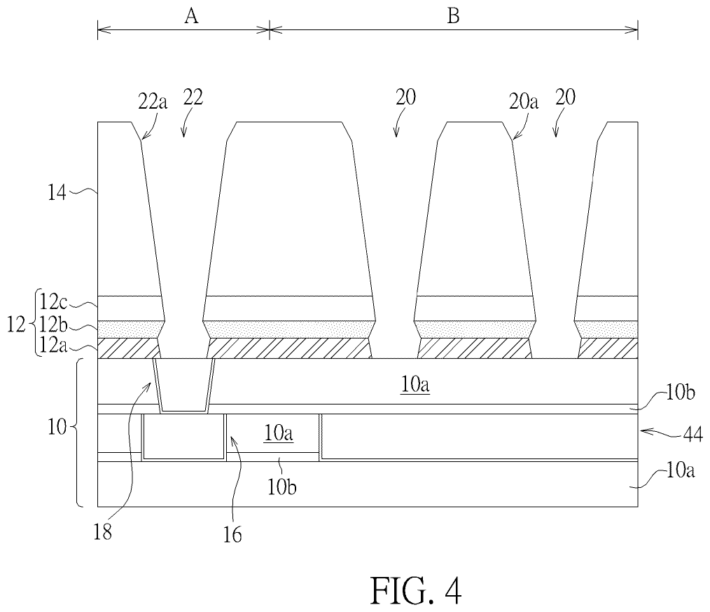

As shown in FIG. 4, after the isotropic etching process, an anisotropic etching process is performed to etch the nitrogen-doped silicon carbide layer 12a by using a second etchant so as to extend the bottom of the first trench 20 and the bottom of the second trench 22 into the nitrogen-doped silicon carbide layer 12a. The second etchant includes CHF₃. Because of the characteristic of the anisotropic etching process, during the process of etching the nitrogen-doped silicon carbide layer 12a, the width of the bottom of the first trench 20 and the width of the bottom of the second trench 22 will continuously and gradually shrink inward. The anisotropic etching process stops when the etchant contacts the first dielectric layer 10 or the first plug 18. Now, the first trench 20 and the second trench 22 are completed.

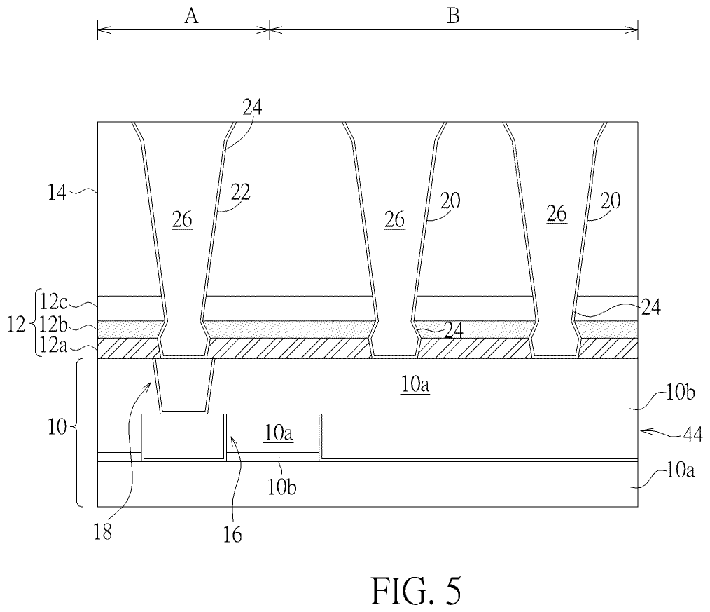

As shown in FIG. 5, a barrier layer 24 is formed to conformally cover the first trench 20 and the second trench 22. The barrier layer 24 in the second trench 22 contacts the first plug 18. Then, a metal layer 26 is formed to fill the first trench 20 and the second trench 22. The metal layer 26 in the first trench 20 will serve as a metal rail for the LCM structure which will be formed afterwards. The metal layer 26 in the second trench 22 will serve as a conductive line in the logic element region A. From the steps in FIG. 2 to FIG. 5, copper damascene process is preferably used to simultaneously manufacture the conductive lines of the logic element region A and the metal rail of the optical element region B. In this way, the manufacturing process of the optical element region B can be simplified.

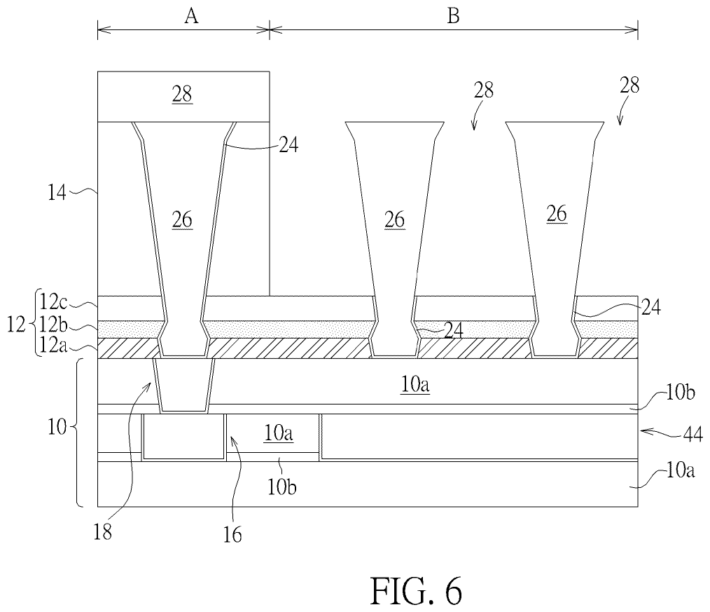

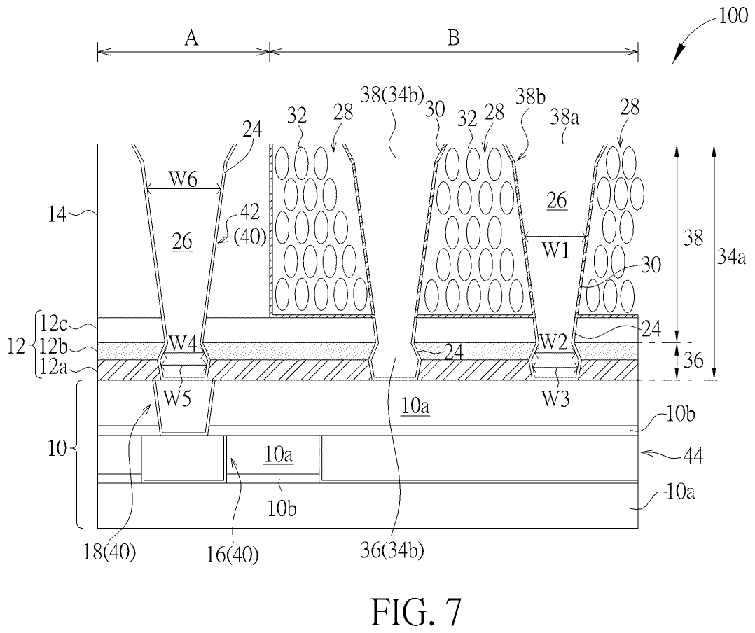

As show in FIG. 6, a mask layer 28 is formed to cover the logic element region A and expose the optical element region B. Then, an entirety of the second dielectric layer 14 in the optical element region B and the barrier layer 24 originally surrounded by the second dielectric layer 14 are removed to form a gap 28. The method of removing the second dielectric layer 14 is preferably by an anisotropic etching process. Now, the silicon nitride layer 12c and the metal layer 26 are exposed through the gap 28. As shown in FIG. 7, the mask layer 28 is removed, and then a protective layer 30 is formed to conformally cover and contact the metal layer 26 and the silicon nitride layer 12c. After that, numerous liquid crystals 32 are provided to fill the gap 28. Now, an LCM structure 100 of the present invention is completely.

As shown in FIG. 7, an LCM structure 100 includes a first dielectric layer 10, a composite dielectric layer 12 and a second dielectric layer 14 stacked from bottom to top. The composite dielectric layer 12 contacts the first dielectric layer 10 and the second dielectric layer 14. The composite dielectric layer 12 includes a nitrogen-doped silicon carbide layer 12a, a silicon oxide layer 12b and a silicon nitride layer 12c stacked from bottom to top. The silicon oxide layer 12b contacts the nitrogen-doped silicon carbide 12a and the silicon nitride layer 12c. The first dielectric layer 10 is a multi-layer dielectric material such as materials alternately stacked by a silicon oxide layer 10a and a nitrogen doped silicon carbide layer 10b. The second dielectric layer 14 is preferably silicon oxide. The first dielectric layer 10, the composite dielectric layer 12 and the second dielectric layer 14 are all divided into a logic element region A and an optical element region B.

A first metal rail 34a and a second metal rail 34b are disposed in the optical element region B. The second metal rail 34b is disposed at one side of the first metal rail 34a. A copper line structure 40 is disposed in the logic element region A. Because the structures of the first metal rail 34a and the second metal rail 34b are the same, only the structure of the first metal rail 34a is described. Please refer to the first metal rail 34a for the structure and materials of the second metal rail 34b.

The first metal rail 34a includes a pedestal 36 and a metal strip 38. The first metal rail 34a embedded in the silicon oxide layer 12b and the nitrogen-doped silicon carbide layer 12a is defined as the pedestal 36. The first metal rail 34a embedded in the silicon nitride layer 12c and protruding on the silicon nitride layer 12c is defined as the metal strip 38. The metal strip 38 has a top surface 38a. A width W1 of the metal strip 38 gradually decreases along a direction from the top surface 38a of the metal strip 38 toward the pedestal 36. Furthermore, the metal strip 38 includes a sidewall, and the sidewall close to the top surface 38a has a corner 38b thereon. The width W2 of the pedestal 36 in the silicon oxide layer 12b continuously and gradually increases in the direction toward the nitrogen-doped silicon carbide layer 12a. The width W3 of the pedestal 36 in the nitrogen-doped silicon carbide layer 12a continuously and gradually decreases in the direction toward the bottom of the pedestal 36. A protective layer 30 covers and contacts the metal strip 38 protruding on the silicon nitride layer 12c. The protective layer 30 is preferably silicon nitride. A barrier layer 24 covers and contacts the pedestal 36 and the metal strip 38 disposed in the silicon nitride layer 12c. The barrier layer 24 preferably includes tantalum nitride, titanium nitride, titanium or tantalum. The first metal rail 34a preferably includes copper.

Moreover, a gap 28 is disposed between the first metal rail 34a and the second metal rail 34b. Numerous liquid crystals 32 fill the gap 28, and some of the liquid crystals 32 contact the protective layer 30. Because the liquid crystals 32 are between the first metal rail 34a and the second metal rail 34b, when voltage is applied to the first metal rail 34a and the second metal rail 34b, the direction of the liquid crystals 32 can be controlled so as to control the refraction direction of incident waves. Furthermore, the corner 38b on the metal strip 38 is turned toward the direction of the adjacent liquid crystals 32. In other words, the sidewall of the metal strip 38 turns outward to define the corner 38b and the metal strip 38 becomes wider toward the top surface 38a because of the corner 38b.

Besides, the copper line structure 40 includes a first conductive line 16, a first plug 18 and a second conductive line 42 stacked from bottom to top. The first conductive line 16 and the first plug 18 are embedded in the first dielectric layer 10. The second conductive line 42 is embedded in the composite dielectric layer 12 and the second dielectric layer 14. The first conductive line 16, the first plug 18 and the second conductive line 42 respectively and preferably include copper and a barrier layer surrounding the copper. The barrier layer preferably includes tantalum nitride, titanium nitride, titanium or tantalum. The width W4 of the second conductive line 42 in the silicon oxide layer 12b continuously and gradually increases in the direction toward the nitrogen-doped silicon carbide layer 12a. The end of the second conductive line 42 is disposed in the nitrogen-doped silicon carbide layer 12a. The width W5 of the second conductive line 42 in the nitrogen-doped silicon carbide layer 12a continuously and gradually decreases in the direction toward the end of the second conductive line 42 in the nitrogen-doped silicon carbide layer 12a. The width W6 of the second conductive line 42 in the second dielectric layer 14 continuously and gradually decreases along the direction toward the silicon oxide layer 12b. In addition, the widths W1/W2/W3/W4/W5/W6 are parallel to the top surface of the composite dielectric layer 12.

In addition, a reflective layer 44 is embedded in the first dielectric layer 10. The reflective layer 44 is disposed directly below the first metal rail 34a and the second metal rail 34b. The reflective layer 44 is preferably formed by using the same fabricating process as the first conductive line 16. Therefore, the material of the reflective layer 44 and the material of the first conductive line 16 are the same, that is, the reflective layer 44 is also formed by copper and a barrier layer surrounding the copper. Moreover, the top surface of the first conductive line 16 is aligned with the top surface of the reflective layer 44.

The first metal rail 34a and the second metal rail 34b of the present invention have the pedestal 36 embedded in the composite dielectric layer 12. Therefore, when the second dielectric layer 14 is removed to form the gap 28, the first metal rail 34a and the second metal rail 34b can be securely fixed by the pedestal 36 to prevent the first metal rail 34a and the second metal rail 34b from falling or collapsing to due to the etching process. In this way, the yield of the LCM structure 100 can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light control metasurface (LCM) structure, comprising:
a composite dielectric layer comprising a nitrogen-doped silicon carbide layer, a silicon oxide layer and a silicon nitride layer stacked from bottom to top;
a first metal rail comprising a pedestal and a metal strip, wherein the first metal rail embedded in the silicon oxide layer and the nitrogen-doped silicon carbide layer is defined as the pedestal, and the first metal rail embedded in the silicon nitride layer and protruding on the silicon nitride layer is defined as the metal strip, and a width of the pedestal in the silicon oxide layer continuously and gradually increases along a direction toward the nitrogen-doped silicon carbide layer;
a second metal rail disposed at one side of the first metal rail, wherein a structure of the first metal rail is the same as a structure of the second metal rail;
a gap disposed between the first metal rail and the second metal rail; and
a plurality of liquid crystals filling the gap.

2. The LCM structure of claim 1, wherein the metal strip has a top surface, and a width of the metal strip gradually decreases from the top surface of the metal strip toward the pedestal.

3. The LCM structure of claim 1, wherein the metal strip includes a sidewall, and the sidewall close to the top surface of the metal strip has a corner.

4. The LCM structure of claim 1, further comprising:
a first dielectric layer disposed below the composite dielectric layer; and
a reflective layer embedded in the first dielectric layer, wherein the reflective layer is disposed directly below the first metal rail and the second metal rail.

5. The LCM structure of claim 4, further comprising:
a second dielectric layer disposed on the composite dielectric layer; and
a copper line structure embedded in the second dielectric layer, the composite dielectric layer and the first dielectric layer, wherein the copper line structure comprises a first conductive line, a first plug and a second conductive line stacked from bottom to top.

6. The LCM structure of claim 5, wherein the second conductive line is embedded in the second dielectric layer and the composite dielectric layer, a width of the second conductive line in the silicon oxide layer continuously and gradually increases along a direction toward the nitrogen-doped silicon carbide layer, and an end of the second conductive line is disposed in the nitrogen-doped silicon carbide layer.

7. The LCM structure of claim 5, wherein a top surface of the first conductive line is aligned with a top surface of the reflective layer.

8. The LCM structure of claim 1, further comprising a protective layer contacting the metal strip protruding on the silicon nitride layer, wherein some of the plurality of liquid crystals contact the protective layer.

9. The LCM structure of claim 1, wherein the silicon oxide layer contacts the nitrogen-doped silicon carbide and the silicon nitride layer.

10. A fabricating method of a light control metasurface (LCM) structure, comprising:
providing a first dielectric layer, a composite dielectric layer and a second dielectric layer stacked from bottom to top, wherein the composite dielectric layer comprises a nitrogen-doped silicon carbide layer, a silicon oxide layer and a silicon nitride layer stacked from bottom to top;
forming a first trench embedded in the second dielectric layer and the silicon nitride layer;
after forming the first trench, performing an isotropic etching process to etch the silicon oxide layer by using a first etchant so as to extend a bottom of the first trench into the silicon oxide layer;
after the isotropic etching process, performing an anisotropic etching process to etch the nitrogen-doped silicon carbide layer by using a second etchant so as to extend the bottom of the first trench into the nitrogen-doped silicon carbide layer;
after the anisotropic etching process, forming a barrier layer to cover the first trench;
after forming the barrier layer, forming a metal layer filling in the first trench;
removing an entirety of the second dielectric layer and the barrier layer in the second dielectric layer to form a gap; and
providing a plurality of liquid crystals to fill the gap.

11. The fabricating method of an LCM structure of claim 10, wherein steps of embedding the first trench in the silicon nitride layer comprises performing another anisotropic etching process by using a third etchant to etch the silicon nitride layer.

12. The fabricating method of an LCM structure of claim 11, wherein the third etchant comprises C₄F₆.

13. The fabricating method of an LCM structure of claim 10, wherein the first etchant comprises CF₄ and the second etchant comprises CHF₃.

14. The fabricating method of an LCM structure of claim 10, further comprising forming a first conductive line, a first plug and a second conductive line stacked from bottom to top, wherein the first conductive line and the first plug are embedded in the first dielectric layer, and the second conductive line is embedded in the composite dielectric layer and the second dielectric layer.

15. The fabricating method of an LCM structure of claim 14, further comprising:
while forming the first trench, simultaneously forming a second trench to be embedded in the second dielectric layer and the silicon nitride layer;
after forming the second trench, performing the isotropic etching process to etch the silicon oxide layer by using the first etchant so as to extend a bottom of the second trench into the silicon oxide layer;
after the isotropic etching process, performing the anisotropic etching process to etch the nitrogen-doped silicon carbide layer by using the second etchant so as to extend the bottom of the second trench into the nitrogen-doped silicon carbide layer;
after the anisotropic etching process, forming the barrier layer to cover the second trench; and
after forming the barrier layer, forming the metal layer filling in the second trench to form the second conductive line.

16. The fabricating method of an LCM structure of claim 15, wherein the barrier layer in the second trench contacts the first plug.

17. The fabricating method of an LCM structure of claim 14, further comprising forming a reflective layer and the first conductive layer simultaneously, wherein the reflective layer and the first conductive layer are embedded in the first dielectric layer, the reflective layer is disposed directly below the first trench, and the top surface of the first conductive line is aligned with the top surface of the reflective layer.

18. The fabricating method of an LCM structure of claim 10, wherein during the isotropic etching process, an opening of the first trench is widened.
